(19) United States
(12) Patent Application Publication
(10) Pub. No.: US 2025/0021068 A1
(43) Pub. Date: Jan. 16, 2025

(54) ELECTRIC POWER AMOUNT REDUCTION CONTROL DEVICE, ELECTRIC POWER AMOUNT REDUCTION CONTROL METHOD, ELECTRIC POWER AMOUNT REDUCTION CONTROL SYSTEM, AND PROGRAM

(71) Applicant: Nippon Telegraph and Telephone Corporation, Tokyo (JP)

(72) Inventors: Hikotoshi NAKAZATO, Musashino-shi, Tokyo (JP); Masashi KANEKO, Musashino-shi, Tokyo (JP)

(21) Appl. No.: 18/711,976

(22) PCT Filed: Dec. 6, 2021
(86) PCT No.: PCT/JP2021/044640

§ 371 Date: May 21, 2024

(51) Int. Cl. G05B 19/042

(52) U.S. Cl. CPC G05B 19/042; G05B 2219/2614

(57) ABSTRACT

A power amount reduction control device (100) includes an external factor acquisition unit (211) that acquires an external factor of air conditioning control, a Situation determination unit (212) that determines a Situation classification based on the external factor, a control value search unit (220) that calculates an air conditioning control value for each Situation classification, an air conditioning control execution unit (230) that controls an air conditioner using the air conditioning control value, a correspondence information generation unit (250) that generates control value power amount correspondence information for each Situation classification, an arrangement pattern calculation unit (310) that calculates an arrangement pattern of virtual resources, a server power consumption amount estimation unit (320) that estimates a server power consumption amount for each arrangement pattern, and an arrangement pattern determination unit (330) that calculates a total amount of the server power consumption amount and the air conditioning power consumption amount in each arrangement pattern and determines an arrangement pattern having a smallest total amount.

### TECHNICAL FIELD

The present invention relates to a power amount reduction control device, a power amount reduction control method, a power amount reduction control system, and a program for reducing a power consumption amount in a data center (hereinafter, may be referred to as “DC”).

### BACKGROUND ART

A proportion of the power consumption amount of air conditioning in a data center (DC) occupies a large proportion, and it is demanded to reduce the power consumption amount of air conditioning according to an increase in the number and scale of DCs. In addition, the data processing amount of the DC tends to increase year by year, and it is necessary to improve power consumption efficiency of the entire DC (power consumption amount of the entire DC relative to a certain amount of data processing).

As a technique for optimizing the power consumption amount of the entire DC in consideration of the power consumption amount of air conditioning and the power consumption amount of the server (IT device), a technique described in Non Patent Literature 1 is disclosed.

In the IT workload allocation cooperative with air conditioning system for data center of Non Patent Literature 1, the transition of the future load of an IT device is predicted by collecting the operation information and the monitoring information of the IT device of the data center, and the power increment of the air conditioning facility according to the power increment of the IT device is calculated. Then, the optimization problem that minimizes an objective function, which is the power amount of the data center, is solved so that the load aggregation rate to the IT device increases in time series, that is, the number of IT devices to be operated is reduced. As a result, the allocation of the IT load (virtual machine) in the IT device for minimizing the power amount of the data center is calculated.

### CITATION LIST

### Non Patent Literature

Non Patent Literature 1: Jun Okitsu and 4 others, “IT Workload Allocation Cooperative with Air Conditioning System for Environment-Conscious Data Center”, FIT (Forum on Information Technology) 2010, 9th Forum on Information Technology, RC-009

### SUMMARY OF INVENTION

### Technical Problem

However, in the technique described in Non Patent Literature 1, a general-purpose rule-based standard that does not depend on facility conditions different for each DC is adopted in an air conditioning power model used for calculating power of an air conditioning facility. Therefore, it has been difficult to perform optimization for reducing the total power amount of the DC in consideration of individual facility conditions such as the arrangement position of the air conditioning facility, the air flow, the server arrangement configuration in the DC, and the thermal cooling efficiency.

The present invention has been made in view of such a point, and an object of the present invention is to reduce the total power consumption amount of the data center including the server power consumption and the air conditioning power consumption according to facility conditions different for each data center.

### Solution to Problem

A power amount reduction control device according to the present invention is a power amount reduction control device that controls a plurality of servers and a plurality of air conditioners included in a data center, in which on a floor of the data center, a plurality of arrangement control sections in which a collective server group in which virtual resources are arranged is arranged and a plurality of air conditioning control sections that is an area for measuring an effect of air conditioning control by the plurality of air conditioners and that is located on either a suction port side or a discharge port side of the server group are set, the power amount reduction control device including: an external factor acquisition unit that acquires information of an external factor related to air conditioning control, including a floor average temperature calculated from an average value of temperatures measured in a plurality of the air conditioning control sections, an outside temperature that is a temperature outside the data center, and a server power consumption amount for each of the arrangement control sections that is a predicted amount when the virtual resource is arranged in the server; a Situation determination unit that divides a value of each external factor into a predetermined range width, defines a Situation classification by combining ranges divided for each external factor, and determines to which Situation classification the acquired information of the external factor belongs; a control value search unit that calculates an air conditioning control value including at least a target temperature to be set for the plurality of air conditioners in each determined Situation classification; an air conditioning control execution unit that executes control of the plurality of air conditioners using the calculated air conditioning control value; a correspondence information generation unit that acquires an air conditioning control value of the plurality of air conditioners and an air conditioning power consumption amount of the plurality of air conditioners when control according to the air conditioning control value is performed, and generates control value power amount correspondence information in which the air conditioning power consumption amount is associated with the air conditioning control value of the plurality of air conditioners for each Situation classification; an arrangement pattern calculation unit that calculates an arrangement pattern for arranging the virtual resource to be newly arranged in any of the plurality of servers; a server power consumption amount estimation unit that estimates a server power consumption amount of a server group belonging to each arrangement control section for each calculated arrangement pattern; and an arrangement pattern determination unit that acquires a Situation classification determination result using the server power consumption amount of each arrangement control section from the Situation determination unit, refers to the control value power amount correspondence information, and acquires, for each arrangement pattern, the air conditioning control values and the air conditioning power consumption amounts of the plurality of air conditioners in the Situation classification, and sums up a server power consumption amount for each arrangement control section, calculates a total amount of the total server power consumption amount that is the sum and the air conditioning power consumption amount in each arrangement pattern, and determines an arrangement pattern having a smallest calculated total amount as an arrangement pattern for arranging the virtual resource.

### Advantageous Effects of Invention

According to the present invention, it is possible to reduce the total power consumption amount of the data center including the server power consumption and the air conditioning power consumption according to facility conditions different for each data center.

### BRIEF DESCRIPTION OF DRAWINGS

FIG. 1 is a diagram illustrating an overall configuration of a power amount reduction control system including a power amount reduction control device according to the present embodiment.

FIG. 2 is a functional block diagram illustrating a configuration example of the power amount reduction control device according to the present embodiment.

FIG. 3 is a diagram for describing a Situation classification according to the present embodiment.

FIG. 4 is a diagram for describing a reward (temperature reward) according to the present embodiment.

FIG. 5 is a diagram for describing a learning phase for searching for an air conditioning control value that satisfies a reward in each Situation classification.

FIG. 6 is a diagram for describing an operation phase in which a fallback operation is performed and a more optimal air conditioning control value is searched for.

FIG. 7 is a flowchart illustrating a flow of arrangement pattern determination processing for determining an arrangement destination of a virtual resource executed by the power amount reduction control device according to the present embodiment.

FIG. 8 is a hardware configuration diagram illustrating an example of a computer that achieves functions of the power amount reduction control device according to the present embodiment.

### DESCRIPTION OF EMBODIMENTS

Next, a mode for carrying out the present invention (hereinafter, referred to as the “present embodiment”) will be described.

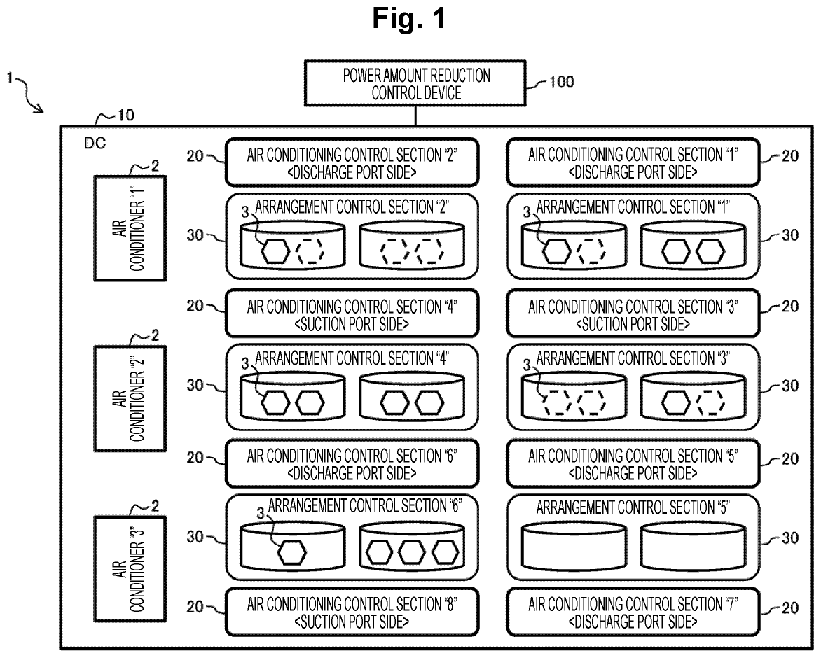

FIG. 1 is a diagram illustrating an overall configuration of a power amount reduction control system 1 including a power amount reduction control device 100 according to the present embodiment.

As illustrated in FIG. 1, the power amount reduction control system 1 is configured to include a data center (DC 10) including a plurality of servers 3 and a plurality of air conditioners 2, and the power amount reduction control device 100 communicatively connected to the plurality of servers 3 and the plurality of air conditioners 2 in the DC 10.

Note that the power amount reduction control device 100 may be provided inside the DC 10 or may be provided in a place different from the DC 10 to control the plurality of DCs 10.

The power amount reduction control device 100 may acquire state information of the air conditioners 2 (in FIG. 1, air conditioners “1”, “2”, and “3”) provided in the DC 10, may transmit air conditioning control information, via an air conditioning management device, which is not illustrated, or may be directly communicably connected to each air conditioner 2 without the air conditioning management device.

In addition, the power amount reduction control device 100 may acquire state information or transmit control information of the servers 3 provided in the DC 10 via a server management device, which is not illustrated, or may be directly communicably connected to each server 3.

In the DC 10 according to the present embodiment, all the servers 3 to be accommodated are divided for each area for arrangement of the plurality of servers 3 as illustrated in FIG. 1, and the area is controlled as an “arrangement control section”. An arrangement control section 30 is an area that accommodates a group of collective servers in which virtual resources are arranged. FIG. 1 illustrates an example in which arrangement control sections “1” to “6” are provided.

Note that, in the DC 10, description will be given assuming that a virtualization base is constructed and operated. As an open source virtualization base, OpenStack (registered trademark), which is software for constructing a cloud environment, and Kubernetes (registered trademark), which is software for operating and managing a containerized workload and service are known. OpenStack is mainly used for management and operation of physical machines and virtual machines (VMs). Kubernetes is mainly used for management and operation of containers.

In the present specification, an application (including one or more containers, one or more VMs, or the like) virtualized in the virtualization base is referred to as a virtual resource. Note that, in Kubernetes, a minimum execution unit of an application is a Pod including one or more containers.

In the present embodiment, an “air conditioning control section” is provided as illustrated in FIG. 1 in association with the arrangement control section 30 of the server group. An air conditioning control section 20 is a collective area for measuring the room temperature effect by the air conditioning control, and faces either the suction port side or the discharge port side of the server 3.

The air blown from the air conditioner 2 is blown out from the air conditioning control section 20 on the suction port side (in FIG. 1, air conditioning control sections “3”, “4”, “7”, and “8”) via, for example, a pipe or the like provided under the floor of the DC 10. Then, the air whose temperature has risen by the heat of each server is taken in from the suction port of the pipe provided in the air conditioning control section 20 on the discharge port (in FIG. 1, air conditioning control sections “1”, “2”, “5”, and “6”), and an air flow returning to the air conditioner 2 is generated.

In each air conditioning control section 20, a plurality of sensors (temperature sensors or the like) is installed. In addition, a sensor (temperature sensor or the like) is also installed outside the DC 10. The power amount reduction control device 100 can acquire information (sensor information) obtained from these sensors via a communication line or the like.

The power amount reduction control device 100 according to the present embodiment predicts the power consumption amount (server power consumption amount) of the arrangement control section 30 in each arrangement pattern of the virtual resource in the server 3 on the basis of virtual resource generation and deletion schedule information. Then, the power amount reduction control device 100 searches for a control value (air conditioning control value) of each air conditioner 2 satisfying a reward (temperature reward) on the basis of the power consumption amount or the like of each arrangement control section 30, and determines an arrangement pattern in which the total amount of the air conditioning power consumption amount and the server power consumption amount when the air conditioner 2 is controlled with the searched air conditioning control value is minimized as the arrangement destination of the virtual resource. In addition, in the operation stage (operation phase), the power amount reduction control device 100 searches for the air conditioning control value having the lowest power consumption amount within the range satisfying the reward by the fallback operation, and further achieves a reduction in the power consumption amount (details will be described below).

### <Power Amount Reduction Control Device>

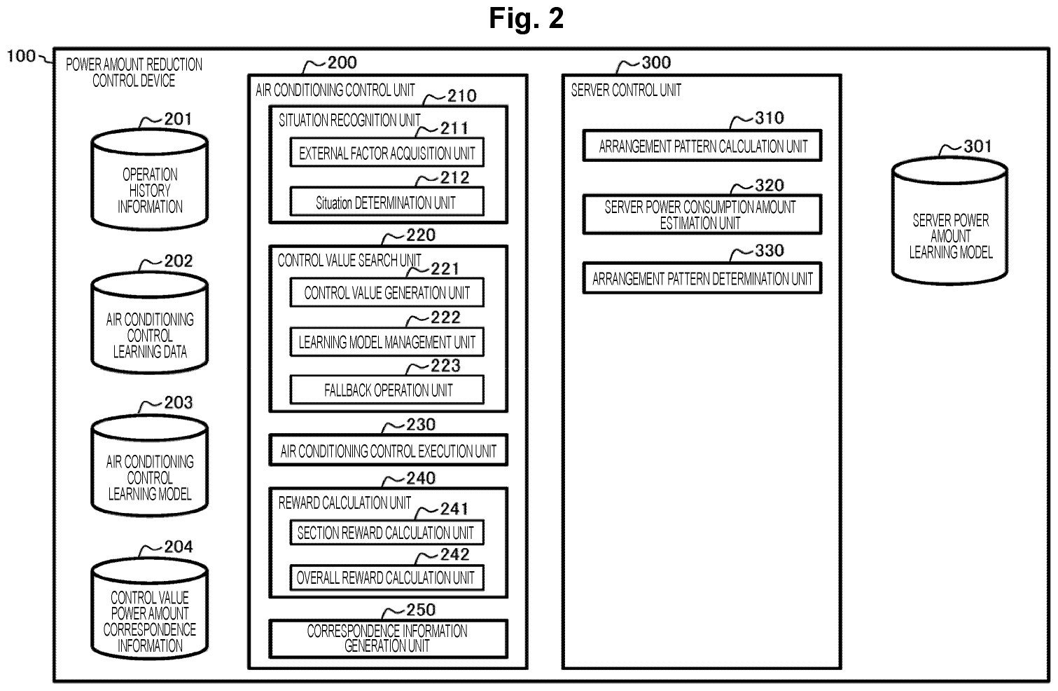

FIG. 2 is a functional block diagram illustrating a configuration example of the power amount reduction control device 100 according to the present embodiment.

The power amount reduction control device 100 predicts the power consumption amount (server power consumption amount) of the arrangement control section 30 in each arrangement pattern of the virtual resource in the server 3, searches for a control value (air conditioning control value) of the air conditioner 2 that satisfies a reward (temperature reward), and determines an arrangement pattern in which the total amount of the server power consumption amount and the air conditioning power consumption amount is minimized as the arrangement destination of the virtual resource.

The power amount reduction control device 100 calculates the power consumption amount (server power consumption amount) of the arrangement control section 30 in each arrangement pattern of the virtual resource in the server 3 using, for example, a learning model generated by machine learning such as a neural network. In addition, the power amount reduction control device 100 calculates an optimal control value of the air conditioner 2 in the calculated power consumption amount (server power consumption amount) using, for example, a learning model generated through the learning phase and the operation phase. Further, in the operation phase, the power amount reduction control device 100 searches for the air conditioning control value having the lowest power consumption amount within the range satisfying the reward by the fallback operation. As a result, the power amount reduction control device 100 determines the optimal arrangement of a virtual server in consideration of the server power consumption amount and the air conditioning power consumption amount, and can reduce the total power amount of the DC 10.

The power amount reduction control device 100 includes a computer including a control unit, an input/output unit, and a storage unit (all not illustrated).

The input/output unit inputs and outputs information to and from each device (each air conditioner 2 and each server 3) in the DC 10. The input/output unit includes a communication interface that transmits and receives information via a communication line, and an input/output interface that inputs and outputs information between an input device such as a keyboard and an output device such as a monitor, which are not illustrated.

The storage unit includes a hard disk, flash memory, random access memory (RAM), or the like.

The storage unit temporarily stores a program for causing each function of the control unit to be executed and information necessary for processing of the control unit. In addition, as information for determining the control value of the air conditioner 2 (air conditioning control value), operation history information 201, air conditioning control learning data 202, an air conditioning control learning model 203, control value power amount correspondence information 204, a server power amount learning model 301, and the like are stored in the storage unit (details will be described below).

The control unit controls overall processing executed by the power amount reduction control device 100, and is configured to include an air conditioning control unit 200 and a server control unit 300 as illustrated in FIG. 2.

The air conditioning control unit 200 uses the average temperature (floor average temperature) of the floor in the DC 10 before control, the outside temperature, and the server power consumption amount for each arrangement control section 30 as Situation components, and calculates an optimal air conditioning control value that satisfies a reward (temperature reward) in each Situation through the learning phase and the operation phase.

The air conditioning control unit 200 includes a situation recognition unit 210, a control value search unit 220, an air conditioning control execution unit 230, a reward calculation unit 240, and a correspondence information generation unit 250.

The situation recognition unit 210 acquires information of an external factor that is a parameter element constituting the Situation classification. Then, the situation recognition unit 210 divides each external factor into a plurality of ranges, sets a combination of the range regions as one Situation, and determines a Situation classification indicating to which Situation the acquired information of the external factor belongs.

The situation recognition unit 210 includes an external factor acquisition unit 211 and a Situation determination unit 212.

The external factor acquisition unit 211 acquires information of the measurement result of the external factor. Here, the external factor is an element that affects an increase or decrease in the air conditioning power consumption amount, and means a parameter element constituting the Situation classification. Here, the external factors are (1) the floor average temperature in the DC 10 before control, (2) the outside temperature, and (3) the server power consumption amount for each arrangement control section 30.

The external factor acquisition unit 211 calculates (1) the floor average temperature in the DC 10 before control as described below. The external factor acquisition unit 211 calculates the average value of the temperatures acquired from the temperature sensor in the air conditioning control section 20, and calculates the average temperature for each air conditioning control section 20. Then, the external factor acquisition unit 211 averages the calculated average temperature for each air conditioning control section 20 by the entire floor, and sets the obtained temperature as the floor average temperature.

(2) The outside temperature is information obtained from the temperature sensor installed outside the DC 10.

(3) The server power consumption amount for each arrangement control section 30 is information calculated by the server control unit 300 (details will be described below).

When acquiring the information of the external factor, the external factor acquisition unit 211 outputs the information to the Situation determination unit 212.

The Situation determination unit 212 determines to which Situation classification the information acquired by the external factor acquisition unit 211 belongs.

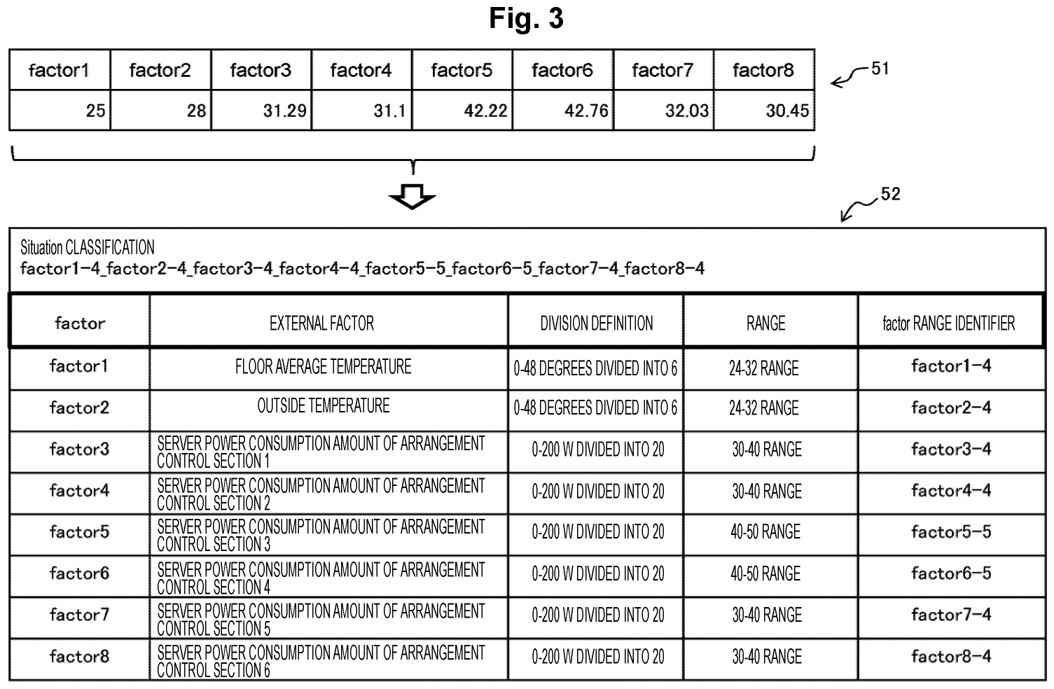

Each external factor is divided into a plurality of ranges according to the characteristics of the external factor between the minimum value and the maximum value. Then, a combination of ranges obtained by dividing each external factor is defined as one Situation. Hereinafter, description will be given with reference to FIG. 3.

As illustrated in FIG. 3, each external factor is defined as a “factor”, and a range to be divided is defined (hereinafter, referred to as “division definition”).

For example, the external factor of “factor1” indicated by Situation classification information 52 in FIG. 3 is “floor average temperature”, and the division definition is “0-48 degrees divided into 6”. The external factor of “factor2” is “outside temperature”, and the division definition is “0-48 degrees divided into 6”. The external factor of “factor3” is “server power consumption amount of arrangement control section 1”, and the division definition is “0-200 W divided into 20”. Similarly, the external factor of “factor8” is “server power consumption amount of arrangement control section 6”, and the division definition is “0-200 W divided into 20”.

Here, it is assumed that the information of the external factor acquired by the Situation determination unit 212 is external factor information 51 illustrated in FIG. 3. In this case, since the value of “factor1” (floor average temperature) is “25”, the Situation determination unit 212 determines that the value falls under “24-32 range” (24 degrees or more and less than 32 degrees) in terms of “range”, and sets “factor range identifier” to “factor1-4”. The “factor range identifier” is, for example, information for identifying a range to belong, such that 0-48 degrees is divided into 6 and 0 degrees or more and less than 8 degrees is “factor1-1”, 8 degrees or more and less than 16 degrees is “factor1-2”, and 16 degrees or more and less than 24 degrees is “factor1-3”. The same applies to other “factors”.

The Situation determination unit 212 combines the information of the “factor range identifiers” of the external factors to obtain the “Situation classification” and determines it as “factor1-4_factor2-4_factor3-4_factor4-4_factor5-5_factor6-5_factor7-4_factor8-4”.

In this way, the Situation determination unit 212 determines the “Situation classification” on the basis of the acquired information of the external factor.

Returning to FIG. 2, the control value search unit 220 calculates an optimal control value of each air conditioner 2 in the situation (Situation) indicated by the determined Situation classification. The control value of the air conditioner 2 (air conditioning control value) is a parameter for controlling the air conditioner 2, and includes at least a temperature (target temperature), and may also include an air volume, a wind direction, and the like. In the present embodiment, description is given assuming that the parameter of the air conditioning control value is the target temperature and the air volume.

The calculation of the air conditioning control value by the control value search unit 220 can be obtained by a method using past actual data or a predetermined rule-based calculation method, but in the present embodiment, an example of constructing a learning model (air conditioning control learning model 203) for calculation will be described.

The control value search unit 220 includes a control value generation unit 221, a learning model management unit 222, and a fallback operation unit 223.

In the learning phase, the control value generation unit 221 randomly generates an air conditioning control value (target temperature, air volume, or the like) for each Situation classification up to a predetermined number of times (N times). At this time, the control value generation unit 221 may turn off any of the plurality of air conditioners 2 and generate the air conditioning control value. Then, the control value generation unit 221 outputs the randomly generated air conditioning control value to the air conditioning control execution unit 230.

Note that when acquiring the randomly generated air conditioning control value, the air conditioning control execution unit 230 executes control of the air conditioner 2. Then, the air conditioning control execution unit 230 stores, as the operation history information 201, the external factor information, the air conditioning control value, the reward (section reward) obtained by the reward calculation unit 240 to be described below when the control is executed, and the information of the air conditioning power consumption amount for each Situation classification.

In addition, when the fallback operation is completed, in the operation phase, the control value generation unit 221 generates the air conditioning control value with reference to the control value power amount correspondence information 204 (details will be described below).

When a predetermined number of times (N times) is reached in the learning phase, the learning model management unit 222 refers to the operation history information 201, captures the external factor information, the air conditioning control value, and the reward (section reward) for each Situation classification, and generates the air conditioning control learning data 202.

Then, the learning model management unit 222 uses the generated air conditioning control learning data 202 to perform machine learning so that the reward is maximized (so that the reward approaches 100%), and generates the air conditioning control learning model 203 for each Situation classification.

In addition, after a predetermined number of times (N times) in the learning phase, the learning model management unit 222 outputs the air conditioning control value (target temperature, air volume, or the like) by inputting the external factor information to the air conditioning control learning model 203 for each Situation classification. Then, the learning model management unit 222 outputs the air conditioning control value calculated by the air conditioning control learning model 203 to the air conditioning control execution unit 230.

Note that when acquiring the air conditioning control value calculated by the air conditioning control learning model 203, the air conditioning control execution unit 230 executes control of the air conditioner 2. Then, the air conditioning control execution unit 230 stores, as the operation history information 201, the external factor information, the air conditioning control value, the reward (section reward) obtained by the reward calculation unit 240 to be described below when the control is executed, and the information of the air conditioning power consumption amount for each Situation classification.

The learning model management unit 222 refers to the operation history information 201, captures the external factor information, the air conditioning control value, and the reward (section reward), which are newly added information, as the air conditioning control learning data 202, and updates the air conditioning control learning model 203 for each Situation classification. Then, after a predetermined number of times (N times), the learning model management unit 222 repeats prediction of the air conditioning control value on the basis of new Situation information.

Note that the learning model management unit 222 ends the learning phase and shifts to the operation phase when a condition based on a predetermined reward described below is satisfied with the air conditioning control learning model 203 of the corresponding Situation classification.

After the air conditioning control learning model 203 of each Situation classification shifts from the learning phase to the operation phase, that is, converges to an air conditioning control value that satisfies a predetermined reward in a certain Situation classification, the fallback operation unit 223 determines whether there is an air conditioning control value having a lower control cost (lower power consumption cost) that satisfies the reward from the converged value by stepwise executing a trial search for the air conditioning control value in a low cost direction. Note that information of the air conditioning control value satisfying the predetermined reward is stored in the control value power amount correspondence information 204 to be described below (details will be described below).

For example, the fallback operation unit 223 further divides Xn (for example, air volume) into M stages (M is an integer of 2 or more) from Xnmin to Xnmax (from the minimum value to the maximum value) with respect to the control value (X1, X2, . . . , Xn) of a certain air conditioner 2. Then, the fallback operation unit 223 decreases Xn (air volume) stepwise in a direction in which the air conditioning control cost is low (power consumption amount is small). The stepwise decrease in control value may be tried in the order of the air conditioner “1”→“2”→“3”, or the like, or the decrease in control value may be collectively tried for the air conditioners “1”, “2”, and “3”, and a predetermined logic for decreasing the control value is set in advance.

Note that when the fallback operation is performed with respect to the target temperature of the air conditioning control value, for example, processing of raising the target temperature by one degree and setting the target temperature is performed so that the air conditioning control cost becomes lower.

Note that after the reward is failed at the Z+1-th fallback (Z is an integer of 0 or more), the fallback operation unit 223 may set the previous Z-th fallback as the air conditioning control value at the time of completion of the fallback.

As another example, the fallback operation unit 223 may execute the one-stage rollback to the previous Z-th fallback after the reward is failed at the Z+1-th fallback, and reconfirm whether the reward is satisfied again at the Z-th fallback. This is for preventing disturbance. Then, in the case of pass in the reconfirmation at the Z-th fallback, the fallback operation unit 223 sets the control value as the air conditioning control value at the time of completion of the fallback. In the case of fail in the reconfirmation at the Z-th fallback, the fallback operation unit 223 repeats the processing of returning to one stage before.

In addition, the fallback operation unit 223 may set the air conditioning control value at the time of completion of the fallback after passing the reconfirmation at the time of the one-stage rollback k times (predetermined times) in a row. Here, in a case where the reward cannot be passed k times in a row, the fallback operation unit 223 can return to one stage before and repeat the calculation of the reward, and determine the control value at the stage after the reward has passed k times in a row as the control value of the lowest control cost.

The air conditioning control execution unit 230 controls each air conditioner 2 on the basis of the information (target temperature, air volume, or the like) of the air conditioning control value in a certain Situation calculated by the control value search unit 220. Note that the air conditioning control execution unit 230 divides the time required from the start of the control to reaching a predetermined target temperature by a predetermined number of stages to make one turn, and sets the target temperature for each turn. Note that for the time required from the start of control to reaching the predetermined target temperature, information obtained in advance from past actual data or the like of the air conditioner 2 is used. As the target temperature for each turn, for example, a value obtained by equally dividing the “temperature before control” to the final “target temperature” by the number of times of control is used.

The air conditioning control execution unit 230 outputs instruction information to each air conditioner 2 on the basis of the air conditioning control value set for each turn.

Note that the air conditioning control execution unit 230 stores, as the operation history information 201, the external factor information, the air conditioning control value for each turn (target temperature, air volume, or the like for each turn), the reward (section reward) obtained by the reward calculation unit 240 to be described below when the control is executed, and the information of the air conditioning power consumption amount for each Situation classification.

The reward calculation unit 240 calculates a reward (temperature reward) as an index for evaluating a result of execution of control according to the air conditioning control value calculated by the control value search unit 220. Then, the reward calculation unit 240 determines whether the control result satisfies a predetermined reward, that is, whether the control result is an air conditioning control value that satisfies a predetermined reward condition.

The reward calculation unit 240 includes a section reward calculation unit 241 and an overall reward calculation unit 242.

The section reward calculation unit 241 defines two types of rewards: a high temperature warning reward and a low temperature warning reward, for each air conditioning control section 20, and calculates a reward of a control result for each turn.

The high temperature warning reward is applied in a case where the temperature before control is higher than the target temperature, that is, in a case where control is performed in a direction in which the room temperature is high and the temperature is lowered. The low temperature warning reward is applied in a case where the temperature before control is lower than the target temperature, that is, in a case where control is performed in a direction in which the room temperature is too low and the temperature is increased.

The section reward calculation unit 241 calculates a reward (section reward) using the indices described below when calculating the reward.
(Index 1) The reward is calculated on the basis of a difference between a target temperature for each turn and an actual temperature at the present time point.
(Index 2) Only the latest turn is focused on and the reward is calculated on the basis of the temperature change of the latest turn.

Note that as the temperature here, for example, an average temperature of a temperature sensor designated in each air conditioning control section 20 is used.

In (Index 1), a difference between “temperature after turn control” and “target temperature for each turn” is obtained.

Then, when the “temperature after turn control” is equal to or lower than the “target temperature for each turn”, the reward is “100%”. In addition, the reward is “−10%” every +1 degrees from the “target temperature for each turn”. Note that this reward is not limited to the above value, and can be arbitrarily set.

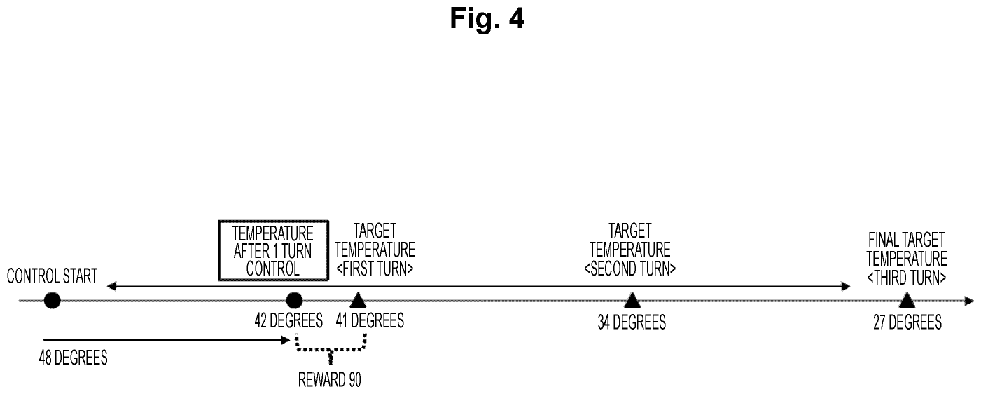

For example, as illustrated in FIG. 4, it is assumed that the temperature at the start of control is 48 degrees and the target temperature of the first turn is 41 degrees. At this time, in a case where the temperature after the turn control of the first turn is 42 degrees, the temperature is 1 degree higher than the target temperature for each turn, and thus the reward is “90%”. Note that FIG. 4 illustrates an example of the high temperature warning reward, but also in the case of the low temperature warning reward, the reward is similarly calculated as “−10%” in a case where the temperature is lower than the target temperature for each turn by, for example, 1 degree.

In (Index 2), the reward is obtained from the temperature change of the latest turn.

Then, in a case where the temperature before the control is higher than the target temperature, a reward (high temperature warning reward) is calculated as in (Formula 1) described below.

$$“ Temperature decreased this time ” / “ Temperature that should originally be decreased ” \times 100 \% \qquad ( Formula 1 )$$

For example, in a case where the temperature decreased this time is 8 degrees and the temperature that should originally be decreased is 10 degrees, the reward is calculated as “80%”. Note that, in a case where the reward as a result of the calculation of (Formula 1) is a value higher than 100%, the reward is 100%.

In addition, in the case of calculating the low temperature warning reward, the reward is calculated by (Formula 2) described below.

$$“ Temperature raised this time ” / “ Temperature that should originally be raised ” \times 100 \% \qquad ( Formula 2 )$$

The section reward calculation unit 241 may evaluate the control result using only (Index 1) or may evaluate the control result using both (Index 1) and (Index 2). Note that when both (Index 1) and (Index 2) are used for evaluation, even when the target temperature for each turn is not reached and the reward does not reach 100% in (Index 1), the control result of the air conditioning control value can be evaluated as a higher reward as the value of the “temperature decreased this time” is larger (the temperature change is larger) in (Index 2).

Note that the information of the reward (section reward) calculated by the section reward calculation unit 241 is stored in the operation history information 201 by the air conditioning control execution unit 230 together with the external factor information, the air conditioning control value for each turn (target temperature, air volume, or the like for each turn), and the information of the air conditioning power consumption amount for each Situation classification.

Returning to FIG. 2, the overall reward calculation unit 242 calculates a reward (overall reward) over the entire floor by using the reward for each air conditioning control section 20 calculated by the section reward calculation unit 241.

The overall reward calculation unit 242 calculates the overall reward by subtracting the reward of a “warning section” from the sum of the rewards (section rewards) for each air conditioning control section 20 (the sum of the maximum rewards) so that 100 points is the perfect score.

In addition, the overall reward calculation unit 242 determines whether the air conditioning control of the entire floor is pass or fail depending on whether the calculated overall reward is equal to or greater than a predetermined threshold (pass threshold) related to the overall reward.

Here, the warning section is defined, for example, as described below.

The case where the section reward is 90% or more is defined as “safe”, the case where the section reward is 85% or more and less than 90% is defined as “caution”, and the case where the section reward is less than 85% is defined as “warning”.

Then, the overall reward is calculated by (Formula 3) described below.

$$( Sum of section rewards - the number of caution sections \times 10 - the number of warning sections \times 30 ) / the number of air conditioning control sections \qquad ( Formula 3 )$$

The overall reward calculation unit 242 sets the pass threshold for the entire area so that fail is determined in a case where, for example, a caution section occupies 20% of the entire area and a warning section occupies 40% of the entire area. Specifically, when the number of air conditioning control sections is “8”, the caution is “−10” points, and the warning is “−30” points, the pass threshold of the entire floor is calculated as described below.

$$( 8 \times 100 - 8 \times 0.2 \times 10 - 8 \times 0.4 \times 30 ) / 8 = 688 / 8 = 86 ( \% )$$

Thus, the overall reward calculation unit 242 determines that the calculated overall reward is passed when the calculated overall reward is equal to or greater than a predetermined pass threshold (86%), and determines that the calculated overall reward is failed when the calculated overall reward is less than the predetermined pass threshold.

Note that when fail is determined by the overall reward calculation unit 242, the processing of the next turn is canceled.

In addition, the learning model management unit 222 ends the learning phase and shifts to the operation phase when the overall reward calculated by the overall reward calculation unit 242 exceeds the predetermined pass threshold (86%) and is determined to have passed with the air conditioning control learning model 203 of the corresponding Situation classification.

Note that the overall reward calculation unit 242 may determine a final pass in the case of pass regarding both the high temperature warning reward and the low temperature warning reward. For example, when the initial temperature before the control of the air conditioner 2 is higher than the target temperature and the control is performed according to the air conditioning control value on the basis of the high temperature warning reward, there is a possibility that the control is performed such that the predetermined pass threshold is exceeded, but the temperature exceeds the target temperature and becomes too low. In this case, air conditioning consumption power is excessively consumed. Thus, in a case where the temperature before the control is lower than the target temperature, the control is performed on the basis of the low temperature warning reward until pass is determined. In this manner, the overall reward calculation unit 242 determines pass regarding both the high temperature warning reward and the low temperature warning reward, so that it is possible to obtain the air conditioning control value that further reduces the air conditioning power consumption amount.

The correspondence information generation unit 250 acquires the air conditioning control value (target temperature, air volume, or the like) of each turn and the power consumption amount of the air conditioner 2 at the time of executing the turn for each Situation classification with respect to the control in which the overall reward calculation unit 242 has determined that the overall reward is passed, and generates the control value power amount correspondence information 204. Note that the air conditioning power consumption amount of the air conditioner 2 is the total power consumption amount of each air conditioner 2 measured by a power consumption amount measurement means, which is not illustrated, for monitoring the air conditioner 2.

In addition, when the fallback operation is completed by the fallback operation unit 223, the correspondence information generation unit 250 updates the control value power amount correspondence information 204 according to the air conditioning control value at which the power consumption cost becomes smaller at the time of completion of the fallback operation and the air conditioning power consumption amount when the air conditioning control value is executed.

The server control unit 300 predicts the server power consumption amount of each server 3 with a possible arrangement pattern (a plurality of arrangement patterns) on the basis of the virtual resource generation and deletion schedule information, and calculates the server power consumption amount for each arrangement control section 30. In addition, the server control unit 300 acquires information of the air conditioning power consumption amount as a result of the execution of the air conditioning control at the time of completion of the fallback operation in the operation phase of the corresponding Situation classification in each arrangement pattern, calculates a total value of the server power consumption amount and the air conditioning power consumption amount in each arrangement pattern, determines an arrangement pattern having the smallest value, and executes the arrangement of the virtual resource.

The server control unit 300 includes an arrangement pattern calculation unit 310, a server power consumption amount estimation unit 320, and an arrangement pattern determination unit 330.

The arrangement pattern calculation unit 310 acquires virtual resource generation and deletion schedule information at the start of each control turn, and obtains information of the amount of virtual resources (for example, the number of CPU cores) to be newly arranged. Then, the arrangement pattern calculation unit 310 calculates an arrangement pattern in which the new virtual resource is arranged in each server 3 on the basis of the latest resource use status (for example, CPU usage rate). Note that after arranging the virtual resource in each server 3, the arrangement pattern calculation unit 310 sets the resource occupancy amount in each server 3 to be equal to or less than server capacity (upper limit value)×predetermined threshold.

The server power consumption amount estimation unit 320 predicts the power consumption amount of each server 3 for each arrangement pattern calculated by the arrangement pattern calculation unit 310 by utilizing the learning model (server power amount learning model 301). Then, the server power consumption amount estimation unit 320 calculates the total server power consumption amount for each arrangement control section 30 in each arrangement pattern on the basis of the server arrangement configuration for each arrangement control section 30.

Specifically, the server power consumption amount estimation unit 320 predicts the power consumption amount of each server 3 for each arrangement pattern using the learning model (server power amount learning model 301) in which the information of the intake port temperature of the server 3 and the resource use status (for example, CPU usage rate, memory usage rate, or the like) is used as input data and the server power consumption amount is used as output data.

Note that the server power amount learning model 301 may generate in advance, as learning data, the information of the intake port temperature, the resource use amount of the server 3, and the server power consumption amount that is result information at that time.

In addition, the server power consumption amount estimation unit 320 calculates the server power consumption amount for each arrangement control section 30 by summing the server power consumption amount of each server 3 in the arrangement control section 30 on the basis of the server arrangement configuration for each arrangement control section 30.

Note that, in the learning phase and the operation phase, the server power consumption amount estimation unit 320 outputs the calculated server power consumption amount for each arrangement control section 30 to the external factor acquisition unit 211 of the air conditioning control unit 200.

The arrangement pattern determination unit 330 sums up the server power consumption amount for each arrangement control section 30 in each arrangement pattern of the virtual resource, calculates the total amount of the total server power consumption amount, which is the total value, and the air conditioning power consumption amount obtained from the control value power amount correspondence information 204, and determines the arrangement pattern having the smallest total amount as the arrangement pattern in which the virtual resource is actually arranged.

Specifically, in the operation phase, the arrangement pattern determination unit 330 executes the processing described below when the fallback operation in each Situation classification is completed and the optimal air conditioning control value for reducing the power consumption amount is stored in the control value power amount correspondence information 204.

The arrangement pattern determination unit 330 first inquires the Situation determination unit 212 of the air conditioning control unit 200 to determine the Situation classification at the present time point. Then, the arrangement pattern determination unit 330 refers to the control value power amount correspondence information 204 in the Situation classification, and acquires, for each arrangement pattern, an air conditioning control value (target temperature, air volume, or the like) and information of an air conditioning power consumption amount when the air conditioner 2 executes the air conditioning control value.

The arrangement pattern determination unit 330 sums up the server power consumption amount of the arrangement control section 30 in each arrangement pattern of the virtual resource, calculates the total amount of the summed up total server power consumption amount and the acquired air conditioning power consumption amount, and determines the arrangement pattern having the smallest total amount as the arrangement pattern in which the virtual resource is actually arranged.

Then, the arrangement pattern determination unit 330 causes a server management device or the like, which is not illustrated, to execute arrangement of the virtual server according to the determined arrangement pattern, and causes the air conditioning control unit 200 to execute control according to an air conditioning control value (target temperature, air volume, or the like) of the air conditioner 2 in the Situation.

### <<Flow of Processing>>

Next, a flow of processing executed by the power amount reduction control device 100 according to the present embodiment will be described.

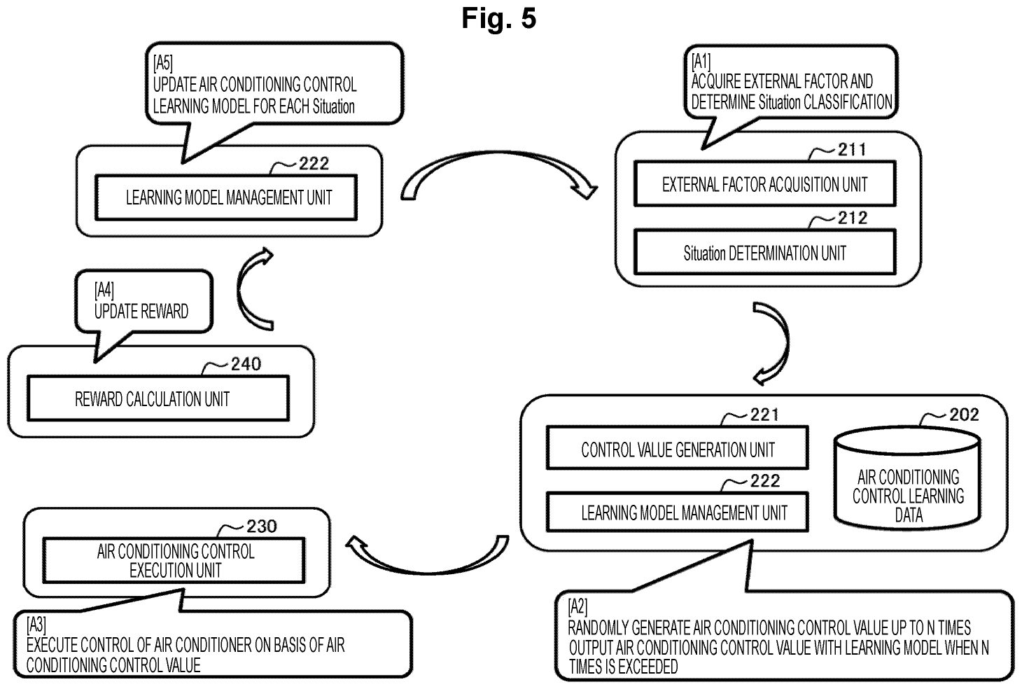

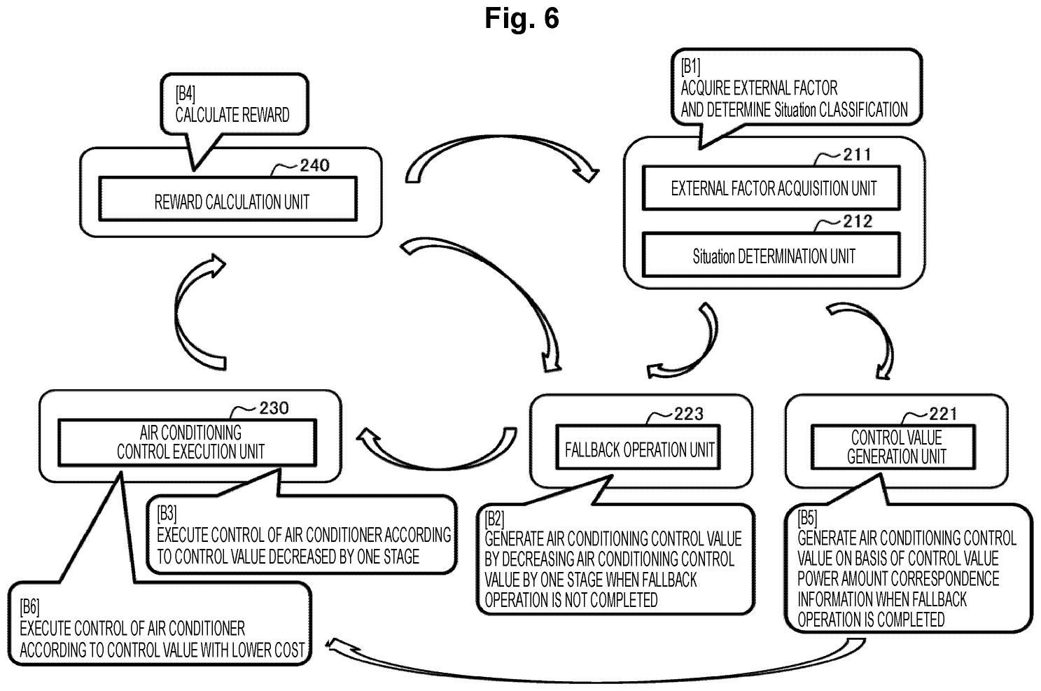

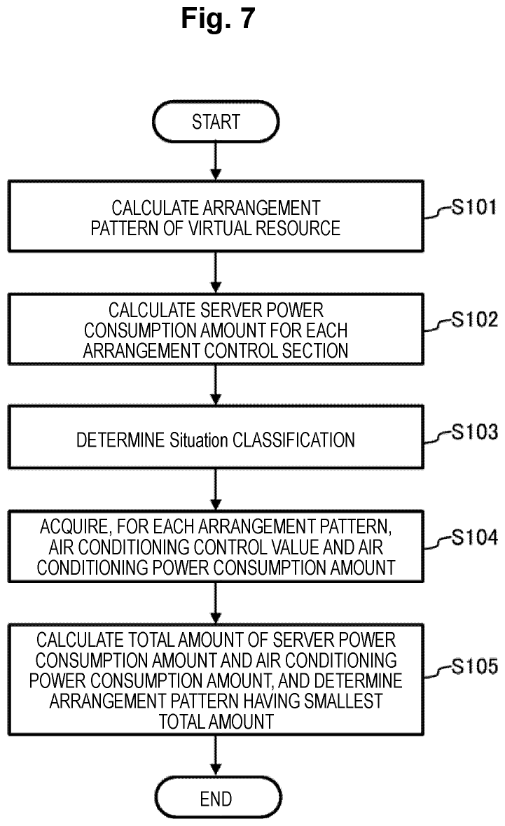

Here, the learning phase (see FIG. 5) for searching for an air conditioning control value satisfying a reward in each Situation classification, the operation phase (see FIG. 6) in which the fallback operation is performed and a more optimal air conditioning control value is searched for, and the arrangement pattern determination processing (see FIG. 7) for determining an arrangement destination of virtual resources will be described.

### <Learning Phase>

FIG. 5 is a diagram for describing a learning phase for searching for an air conditioning control value that satisfies a reward in each Situation classification.

In the learning phase, the power amount reduction control device 100 performs the search by repeating the PDCA cycle until the air conditioning control value satisfying the reward (temperature reward) in each Situation classification is found.

First, in step A1, the situation recognition unit 210 (external factor acquisition unit 211) of the power amount reduction control device 100 acquires information of an external factor (floor average temperature, outside temperature, server power consumption amount for each arrangement control section 30).

Then, the situation recognition unit 210 (Situation determination unit 212) determines to which Situation classification the acquired information of the external factor belongs.

Note that step A1 corresponds to Plan (plan) of the PDCA cycle.

Next, in step A2 (P (Plan): plan), the control value search unit 220 calculates an air conditioning control value for each Situation classification. Note that the control value generation unit 221 of the control value search unit 220 randomly searches for the air conditioning control value up to N times. Then, when the N times is reached, the learning model management unit 222 of the control value search unit 220 causes the air conditioning control learning model 203 to learn learning data (external factor information and information of reward associated with the air conditioning control value). As a result, when the N times is exceeded, the learning model management unit 222 outputs the information of the air conditioning control value by inputting the Situation information to the air conditioning control learning model 203.

Subsequently, in step A3 (D (Do): do), the air conditioning control execution unit 230 executes the actual control of each air conditioner 2 on the basis of the air conditioning control value (target temperature, air volume, or the like) calculated by the control value search unit 220.

Next, in step A4 (C (Check): check), the reward calculation unit 240 calculates a reward (section reward and overall reward) that is a result of executing the control of the air conditioning control value. Here, in a case where the calculated overall reward is less than the pass determination threshold and is determined to be failed, the reward calculation unit 240 does not execute processing of subsequent turns.

When the overall reward is passed in step A4, in the next step A5 (A (Action): act), the control value search unit 220 (learning model management unit 222) updates the air conditioning control learning model 203 for each Situation classification on the basis of learning data (air conditioning control learning data 202) of the external factor information and the reward associated with the air conditioning control value.

In the learning phase, the search is performed by applying this PDCA cycle until a control value in which the reward (overall reward) is determined to be passed for each Situation classification is found. When the air conditioning control value that satisfies the reward (overall reward) is found, the correspondence information generation unit 250 generates, for each Situation classification, the control value power amount correspondence information 204 that stores the air conditioning control value (target temperature, air volume, or the like) of each turn and the power consumption amount (air conditioning power consumption amount) of the entire air conditioners 2 when the turn is executed. As a result, the corresponding Situation classification is shifted from the learning phase to the operation phase.

### <Operation Phase>

FIG. 6 is a diagram for describing an operation phase in which the fallback operation is performed and a more optimal air conditioning control value is searched for.

In the operation phase, in an initial state (state in which the fallback operation is not completed), by the processing of the control value search unit 220 (fallback operation unit 223), the control value is decreased by one stage from the control value with the minimum air conditioning control cost satisfying the current reward, the PDCA cycle is applied, and after a control value at a stage at which the control value cannot be decreased any more is found, the fallback operation is completed. Then, when the fallback operation of the corresponding Situation classification is completed, the air conditioning control is executed by calling the air conditioning control value at the time of completion of the fallback operation.

First, in step B1 (P (Plan): plan), the situation recognition unit 210 (external factor acquisition unit 211) of the power amount reduction control device 100 acquires information of an external factor (floor average temperature, outside temperature, server power consumption amount for each arrangement control section).

Then, the situation recognition unit 210 (Situation determination unit 212) determines to which Situation classification the acquired information of the external factor belongs.

Next, in step B2 (P (Plan): plan), when the fallback operation is not completed, the control value search unit 220 (fallback operation unit 223) refers to the control value power amount correspondence information 204 in which the air conditioning control value satisfying a predetermined reward is stored, and decreases the control value by one stage from the air conditioning control value of the lowest cost satisfying the current reward to generate an air conditioning control value.

Subsequently, in step B3 (D (Do): do), the air conditioning control execution unit 230 executes the control of each air conditioner 2 on the basis of the control value (target temperature, air volume, or the like) calculated by the control value search unit 220, that is, a control value decreased by one stage.

Next, in step B4 (C (Check): check), the reward calculation unit 240 calculates a reward (section reward and overall reward) that is a result of executing the control of the air conditioning control value. When the overall reward is passed, the fallback operation unit 223 further decreases the control value by one stage (step B2), and causes the air conditioning control execution unit 230 to perform control of the air conditioner 2 in step B3 (A (Action): act). Then, the fallback operation unit 223 determines a control value one stage before the control value at which the reward fails as the control value of the lowest control cost.

Note that the fallback operation unit 223 may execute the one-stage rollback to the previous Z-th fallback after the reward fails at the Z+1-th fallback, and reconfirm whether the reward is satisfied again at the Z-th fallback. Then, in the case of pass in the reconfirmation at the Z-th fallback, the fallback operation unit 223 sets the control value as the air conditioning control value at the time of completion of the fallback. In the case of fail in the reconfirmation at the Z-th fallback, the fallback operation unit 223 repeats the processing of returning to one stage before, and sets the control value at the stage of the reward passing as the air conditioning control value at the time of completion of the fallback.

When the control value having the lowest control cost is determined (when the fallback operation is completed), the correspondence information generation unit 250 updates the control value power amount correspondence information 204 according to the air conditioning control value at which the power consumption cost becomes smaller at the time of completion of the fallback operation and the air conditioning power consumption amount when the air conditioning control value is executed.

When the processing returns to step B1 in a state where the fallback operation is completed, the situation recognition unit 210 (external factor acquisition unit 211) acquires information of the external factor (floor average temperature, outside temperature, server power consumption amount for each arrangement control section), and the Situation determination unit 212 determines to which Situation classification the acquired information of the external factor belongs.

Then, in step B5, when the fallback operation of the Situation classification is completed, the control value search unit 220 (control value generation unit 221) generates the air conditioning control value on the basis of the updated control value power amount correspondence information 204.

Next, the processing proceeds to step B6, and the air conditioning control execution unit 230 executes control of the air conditioner 2 on the basis of the air conditioning control value in a state where the fallback operation is completed.

By performing this processing in each Situation classification, the power amount reduction control device 100 can generate, as the control value power amount correspondence information 204, information of the air conditioning control value capable of further reducing the air conditioning power consumption and the air conditioning power consumption amount at that time for each Situation classification.

### <Arrangement Pattern Determination Processing for Determining Arrangement Destination of Virtual Resource>

FIG. 7 is a flowchart illustrating a flow of arrangement pattern determination processing for determining an arrangement destination of a virtual resource executed by the power amount reduction control device 100 according to the present embodiment.

First, the server control unit 300 (arrangement pattern calculation unit 310) of the power amount reduction control device 100 acquires virtual resource generation and deletion schedule information at the start of each control turn. Then, the arrangement pattern calculation unit 310 calculates an arrangement pattern in which a new virtual resource is added (or deleted) to the current use status of the server resource (step S101).

Next, the server power consumption amount estimation unit 320 of the server control unit 300 predicts the server power consumption amount of each server 3 for each arrangement pattern calculated by the arrangement pattern calculation unit 310 by using, for example, the server power amount learning model 301. Then, the server power consumption amount estimation unit 320 sums up the server power consumption amount of the server 3 in each arrangement control section 30 for each arrangement pattern, and calculates the server power consumption amount for each arrangement control section 30 (step S102).

Subsequently, the situation recognition unit 210 (external factor acquisition unit 211) of the air conditioning control unit 200 acquires information of an external factor (floor average temperature, outside temperature, server power consumption amount for each arrangement control section) for each arrangement pattern. Then, the Situation determination unit 212 determines the Situation classification (step S103).

Next, the arrangement pattern determination unit 330 refers to the control value power amount correspondence information 204 in the determined Situation classification, and acquires, for each arrangement pattern, the air conditioning control value in a state where the fallback operation of the operation phase is completed and information of the air conditioning power consumption amount when the control is executed (step S104).

Subsequently, the arrangement pattern determination unit 330 sums up the server power consumption amount for each arrangement control section 30 in each arrangement pattern, calculates the total amount of the summed up total server power consumption amount and the air conditioning power consumption amount, and determines the arrangement pattern having the smallest total amount (step S105).

Then, information of the arrangement pattern of the virtual server determined by the arrangement pattern determination unit 330 is transmitted to a server management device, which is not illustrated, and causes actual arrangement control of the virtual server to be executed.

In this way, the power amount reduction control device 100 can reduce the total power consumption amount of the data center including the server power consumption and the air conditioning power consumption according to facility conditions different for each data center (DC) 10.

### <Hardware Configuration>

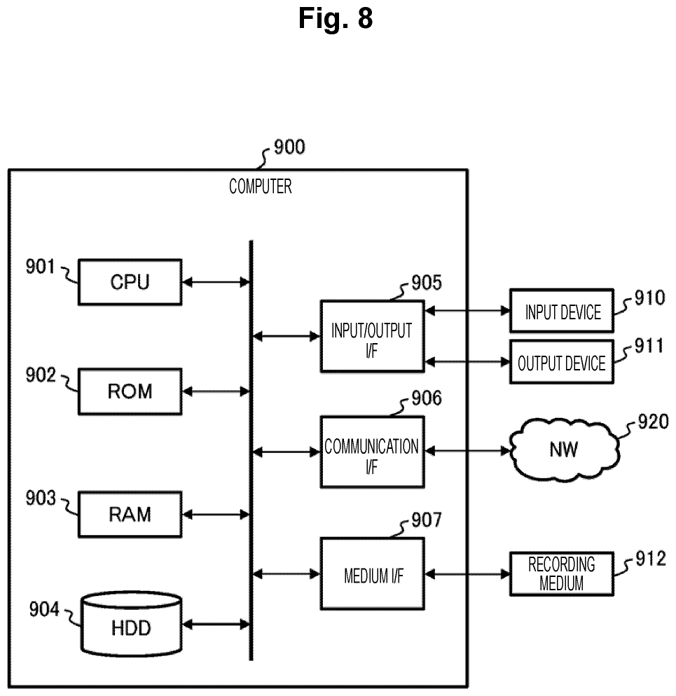

The power amount reduction control device 100 according to the present embodiment is implemented by, for example, a computer 900 having a configuration as illustrated in FIG. 8.

FIG. 8 is a hardware configuration diagram illustrating an example of the computer 900 that achieves functions of the power amount reduction control device 100 according to the present embodiment. The computer 900 includes a central processing unit (CPU) 901, read only memory (ROM) 902, RAM 903, a hard disk drive (HDD) 904, an input/output interface (I/F) 905, a communication I/F 906, and a medium I/F 907.

The CPU 901 operates on the basis of a program stored in the ROM 902 or the HDD 904, and performs control with a control unit. The ROM 902 stores a boot program to be executed by the CPU 901 when the computer 900 is started, a program related to hardware of the computer 900, and the like.

The CPU 901 controls an input device 910 such as a mouse or a keyboard and an output device 911 such as a display or a printer via the input/output I/F 905. The CPU 901 acquires data from the input device 910 and outputs generated data to the output device 911 via the input/output I/F 905. Note that a graphics processing unit (GPU) or the like may be used as a processor together with the CPU 901.

The HDD 904 stores a program to be executed by the CPU 901, data to be used by the program, and the like. The communication I/F 906 receives data from another device via a communication network (for example, network (NW) 920), outputs the data to the CPU 901, and transmits data generated by the CPU 901 to another device via the communication network.

The medium I/F 907 reads a program or data stored in a recording medium 912, and outputs the program or data to the CPU 901 via the RAM 903. The CPU 901 loads a program related to target processing from the recording medium 912 onto the RAM 903 via the medium I/F 907, and executes the loaded program. The recording medium 912 is an optical recording medium such as a digital versatile disc (DVD) or a phase change rewritable disk (PD), a magneto-optical recording medium such as a magneto optical disk (MO), a magnetic recording medium, a semiconductor memory, or the like.

For example, in a case where the computer 900 functions as the power amount reduction control device 100 of the present invention, the CPU 901 of the computer 900 achieves the function of the power amount reduction control device 100 by executing the program loaded on the RAM 903. In addition, the HDD 904 stores data in the RAM 903. The CPU 901 reads the program related to the target processing from the recording medium 912, and executes the program. Additionally, the CPU 901 may read the program related to the target processing from another device via the communication network (NW 920).

### Effects

Hereinafter, effects of the power amount reduction control device 100 and the like according to the present invention will be described.

A power amount reduction control device according to the present invention is a power amount reduction control device 100 that controls a plurality of servers 3 and a plurality of air conditioners 2 included in a data center 10, in which on a floor of the data center 10, a plurality of arrangement control sections 30 in which a collective server group in which virtual resources are arranged is arranged and a plurality of air conditioning control sections 20 that is an area for measuring an effect of air conditioning control by the plurality of air conditioners 2 and that is located on either a suction port side or a discharge port side of the server group are set, the power amount reduction control device 100 including: an external factor acquisition unit 211 that acquires information of an external factor related to air conditioning control, including a floor average temperature calculated from an average value of temperatures measured in a plurality of the air conditioning control sections 20, an outside temperature that is a temperature outside the data center 10, and a server power consumption amount for each of the arrangement control sections that is a predicted amount when the virtual resource is arranged in the server 3; a Situation determination unit 212 that divides a value of each external factor into a predetermined range width, defines a Situation classification by combining ranges divided for each external factor, and determines to which Situation classification the acquired information of the external factor belongs; a control value search unit 220 that calculates an air conditioning control value including at least a target temperature to be set for the plurality of air conditioners 2 in each determined Situation classification; an air conditioning control execution unit 230 that executes control of the plurality of air conditioners 2 using the calculated air conditioning control value; a correspondence information generation unit 250 that acquires an air conditioning control value of the plurality of air conditioners 2 and an air conditioning power consumption amount of the plurality of air conditioners 2 when control according to the air conditioning control value is performed, and generates control value power amount correspondence information 204 in which the air conditioning power consumption amount is associated with the air conditioning control value of the plurality of air conditioners 2 for each Situation classification; an arrangement pattern calculation unit 310 that calculates an arrangement pattern for arranging the virtual resource to be newly arranged in any of the plurality of servers 3; a server power consumption amount estimation unit 320 that estimates a server power consumption amount of a server group belonging to each arrangement control section 30 for each calculated arrangement pattern; and an arrangement pattern determination unit 330 that acquires a Situation classification determination result using the server power consumption amount of each arrangement control section 30 from the Situation determination unit 212, refers to the control value power amount correspondence information 204, and acquires, for each arrangement pattern, the air conditioning control values and the air conditioning power consumption amounts of the plurality of air conditioners 2 in the Situation classification, and sums up a server power consumption amount for each arrangement control section 30, calculates a total amount of the total server power consumption amount that is the sum and the air conditioning power consumption amount in each arrangement pattern, and determines an arrangement pattern having a smallest calculated total amount as an arrangement pattern for arranging the virtual resource.

In this way, when newly arranging the virtual resource, the power amount reduction control device 100 can determine the optimal arrangement pattern of the virtual resource for reducing the power consumption amount of the entire data center 10 in consideration of the server power consumption amount and the air conditioning power consumption amount.

The power amount reduction control device 100 can determine the arrangement of the virtual server in consideration of different facility conditions (air flow, server arrangement configuration, air conditioning arrangement position, thermal cooling efficiency, or the like) in the arrangement control section 30 and the air conditioning control section 20 set in the data center 10 and a temperature difference for each air conditioning control section 20 due to a heat reservoir. Therefore, it is possible to achieve a reduction in power consumption amount suitable for each situation of each data center 10.

In addition, the power amount reduction control device 100 includes: a reward calculation unit 240 that calculates a reward for evaluating a result of the air conditioning control execution unit 230 controlling the plurality of air conditioners 2 according to the air conditioning control value by using the target temperature as an index, and the control value search unit 220 includes a learning model management unit 222 that generates an air conditioning control learning model 203 for each Situation classification by performing machine learning such that the reward is maximized using the information of the external factor, the air conditioning control value of the plurality of air conditioners 2, and the reward as learning data, the air conditioning control learning model 203 outputting the air conditioning control value of the plurality of air conditioners 2 when the information of the external factor is input.

As described above, the power amount reduction control device 100 can generate the optimal air conditioning control value of the air conditioner 2 for each Situation classification by generating the air conditioning control learning model 203 for each Situation classification.

In addition, the power amount reduction control device 100 includes: a reward calculation unit 240 that calculates a reward for evaluating a result of the air conditioning control execution unit 230 controlling the plurality of air conditioners 2 according to the air conditioning control value by using the target temperature as an index; and a fallback operation unit 223, when the reward satisfies a predetermined reward condition, the correspondence information generation unit 250 generates the control value power amount correspondence information 204 in the Situation classification, the fallback operation unit 223 performs, by fallback operation, a search for an air conditioning control value with a lower power consumption cost within a range satisfying the predetermined reward condition for each Situation classification, and the correspondence information generation unit 250 updates the control value power amount correspondence information 204 for each Situation classification using the air conditioning control value searched by the fallback operation unit 223.

As described above, the power amount reduction control device 100 can search for the air conditioning control value with a smaller power consumption cost by the fallback operation within the range satisfying the predetermined reward condition. Thus, it is possible to further reduce the power consumption amount of the entire data center 10.

In addition, in the power amount reduction control device 100, the fallback operation unit 223 defines the air conditioning control value in M (an integer of 2 or more) stages between a minimum value and a maximum value, and repeats processing of stepwise lowering the air conditioning control value in a direction in which the power consumption amount is reduced when the calculated reward satisfies a predetermined reward condition and is passed, and determines a control value one stage before the air conditioning control value at which the calculated reward does not satisfy the predetermined reward condition and fails as an air conditioning control value with the lowest power consumption cost.

In this manner, the power amount reduction control device 100 can search for the air conditioning control value with lower power consumption cost within the range satisfying the predetermined reward condition.

In addition, in the power amount reduction control device 100, the fallback operation unit 223 defines the air conditioning control value in M (an integer of 2 or more) stages between a minimum value and a maximum value, and repeats processing of stepwise lowering the air conditioning control value in a direction in which the power consumption amount is reduced when the calculated reward satisfies a predetermined reward condition and is passed, reconfirms whether the reward is satisfied again with a control value one stage before the air conditioning control value at which the calculated reward does not satisfy the predetermined reward condition and fails, repeats reconfirmation as to whether the reward is satisfied with a control value further one stage before when the calculated reward fails in the reconfirmation, and determines an air conditioning control value at which the reward is passed in the reconfirmation as an air conditioning control value with the lowest power consumption cost.

In this manner, the power amount reduction control device 100 can prevent disturbance and search for the air conditioning control value with lower power consumption cost within the range satisfying the predetermined reward condition.

Note that the present invention is not limited to the above-described embodiment, and many modifications can be made by those skilled in the art within the technical idea of the present invention.

### REFERENCE SIGNS LIST

1 Power amount reduction control system
2 Air conditioner
3 Server
10 Data center (DC)
20 Air conditioning control section
30 Arrangement control section
100 Power amount reduction control device
200 Air conditioning control unit
201 Operation history information
202 Air conditioning control learning data
203 Air conditioning control learning model
204 Control value power amount correspondence
information
210 Situation recognition unit
211 External factor acquisition unit
212 Situation determination unit
220 Control value search unit
221 Control value generation unit
222 Learning model management unit
223 Fallback operation unit
230 Air conditioning control execution unit
240 Reward calculation unit
241 Section reward calculation unit
242 Overall reward calculation unit
250 Correspondence information generation unit
300 Server control unit
301 Server power amount learning model
310 Arrangement pattern calculation unit
320 Server power consumption amount estimation unit
330 Arrangement pattern determination unit

1. A power amount reduction control device that controls a plurality of servers and a plurality of air conditioners included in a data center, wherein
on a floor of the data center, a plurality of arrangement control sections in which a collective server group in which virtual resources are arranged is arranged and a plurality of air conditioning control sections that is an area for measuring an effect of air conditioning control by the plurality of air conditioners and that is located on either a suction port side or a discharge port side of the server group are set,
the power amount reduction control device comprising:
an external factor acquisition unit, including one or more processors, configured to acquire information of an external factor related to air conditioning control, including a floor average temperature calculated from an average value of temperatures measured in a plurality of the air conditioning control sections, an outside temperature that is a temperature outside the data center, and a server power consumption amount for each of the arrangement control sections that is a predicted amount when the virtual resource is arranged in the server;
a Situation determination unit, including one or more processors, configured to divide a value of each external factor into a predetermined range width, define a Situation classification by combining ranges divided for each external factor, and determine to which Situation classification the acquired information of the external factor belongs;
a control value search unit, including one or more processors, configured to calculate an air conditioning control value including at least a target temperature to be set for the plurality of air conditioners in each determined Situation classification;
an air conditioning control execution unit, including one or more processors, configured to execute control of the plurality of air conditioners using the calculated air conditioning control value;
a correspondence information generation unit, including one or more processors, configured to acquire an air conditioning control value of the plurality of air conditioners and an air conditioning power consumption amount of the plurality of air conditioners when control according to the air conditioning control value is performed, and generate control value power amount correspondence information in which the air conditioning power consumption amount is associated with the air conditioning control value of the plurality of air conditioners for each Situation classification;
an arrangement pattern calculation unit, including one or more processors, configured to calculate an arrangement pattern for arranging the virtual resource to be newly arranged in any of the plurality of servers;
a server power consumption amount estimation unit, including one or more processors, configured to estimate a server power consumption amount of a server group belonging to each arrangement control section for each calculated arrangement pattern; and
an arrangement pattern determination unit, including one or more processors, configured to acquire a Situation classification determination result using the server power consumption amount of each arrangement control section from the Situation determination unit, refer to the control value power amount correspondence information, and acquire, for each arrangement pattern, the air conditioning control values and the air conditioning power consumption amounts of the plurality of air conditioners in the Situation classification, and sum up a server power consumption amount for each arrangement control section, calculate a total amount of a total server power consumption amount that is the sum and the air conditioning power consumption amount in each arrangement pattern, and determine an arrangement pattern having a smallest calculated total amount as an arrangement pattern for arranging the virtual resource.

2. The power amount reduction control device according to claim 1, further comprising:
a reward calculation unit, including one or more processors, configured to calculate a reward for evaluating a result of the air conditioning control execution unit controlling the plurality of air conditioners according to the air conditioning control value by using the target temperature as an index, wherein
the control value search unit includes
a learning model management unit, including one or more processors, configured to generate an air conditioning control learning model for each Situation classification by performing machine learning such that the reward is maximized using the information of the external factor, the air conditioning control value of the plurality of air conditioners, and the reward as learning data, the air conditioning control learning model is configured to output the air conditioning control value of the plurality of air conditioners when the information of the external factor is input.

3. The power amount reduction control device according to claim 1, further comprising:
a reward calculation unit, including one or more processors, configured to calculate a reward for evaluating a result of the air conditioning control execution unit controlling the plurality of air conditioners according to the air conditioning control value by using the target temperature as an index; and
a fallback operation unit, wherein
when the reward satisfies a predetermined reward condition, the correspondence information generation unit is configured to generate the control value power amount correspondence information in the Situation classification,
the fallback operation unit is configured to perform, by fallback operation, a search for an air conditioning control value with a lower power consumption cost within a range satisfying the predetermined reward condition for each Situation classification, and
the correspondence information generation unit is configured to update the control value power amount correspondence information for each Situation classification using the air conditioning control value searched by the fallback operation unit.

4. The power amount reduction control device according to claim 3, wherein
the fallback operation unit is configured to:
define the air conditioning control value in M (an integer of 2 or more) stages between a minimum value and a maximum value,
repeat processing of stepwise lowering the air conditioning control value in a direction in which the power consumption amount is reduced when the calculated reward satisfies a predetermined reward condition and is passed, and
determine a control value one stage before the air conditioning control value at which the calculated reward does not satisfy the predetermined reward condition and fails as an air conditioning control value with a lowest power consumption cost.

5. The power amount reduction control device according to claim 3, wherein
the fallback operation unit is configured to:
define the air conditioning control value in M (an integer of 2 or more) stages between a minimum value and a maximum value, and
repeat processing of stepwise lowering the air conditioning control value in a direction in which the power consumption amount is reduced when the calculated reward satisfies a predetermined reward condition and is passed,
reconfirm whether the reward is satisfied again with a control value one stage before the air conditioning control value at which the calculated reward does not satisfy the predetermined reward condition and fails,
repeat reconfirmation as to whether the reward is satisfied with a control value further one stage before when the calculated reward fails in the reconfirmation, and
determine an air conditioning control value at which the reward is passed in the reconfirmation as an air conditioning control value with a lowest power consumption cost.

6. A power amount reduction control method for a power amount reduction control device that controls a plurality of servers and a plurality of air conditioners included in a data center, wherein
on a floor of the data center, a plurality of arrangement control sections in which a collective server group in which virtual resources are arranged is arranged and a plurality of air conditioning control sections that is an area for measuring an effect of air conditioning control by the plurality of air conditioners and that is located on either a suction port side or a discharge port side of the server group are set, and
the power amount reduction control method comprising:
acquiring information of an external factor related to air conditioning control, including a floor average temperature calculated from an average value of temperatures measured in a plurality of the air conditioning control sections, an outside temperature that is a temperature outside the data center, and a server power consumption amount for each of the arrangement control sections that is a predicted amount when the virtual resource is arranged in the server;
dividing a value of each external factor into a predetermined range width;
defining a Situation classification by combining ranges divided for each external factor;
determining to which Situation classification the acquired information of the external factor belongs;
calculating an air conditioning control value including at least a target temperature to be set for the plurality of air conditioners in each determined Situation classification;
executing control of the plurality of air conditioners using the calculated air conditioning control value;
acquiring an air conditioning control value of the plurality of air conditioners and an air conditioning power consumption amount of the plurality of air conditioners when control according to the air conditioning control value is performed;
generating control value power amount correspondence information in which the air conditioning power consumption amount is associated with the air conditioning control value of the plurality of air conditioners for each Situation classification;
calculating an arrangement pattern for arranging the virtual resource to be newly arranged in any of the plurality of servers;
estimating a server power consumption amount of a server group belonging to each arrangement control section for each calculated arrangement pattern;
acquiring a Situation classification determination result using the server power consumption amount of each arrangement control section;
referring to the control value power amount correspondence information;
acquiring, for each arrangement pattern, the air conditioning control values and the air conditioning power consumption amounts of the plurality of air conditioners in the Situation classification;
summing up a server power consumption amount for each arrangement control section;
calculating a total amount of a total server power consumption amount that is the sum and the air conditioning power consumption amount in each arrangement pattern; and
determining an arrangement pattern having a smallest calculated total amount as an arrangement pattern for arranging the virtual resource.

7. A power amount reduction control system comprising: a data center that includes a plurality of servers and a plurality of air conditioners; and a power amount reduction control device that controls a power consumption amount of the data center, wherein
on a floor of the data center, a plurality of arrangement control sections in which a collective server group in which virtual resources are arranged is arranged and a plurality of air conditioning control sections that is an area for measuring an effect of air conditioning control by the plurality of air conditioners and that is located on either a suction port side or a discharge port side of the server group are set, and
the power amount reduction control device comprising:
an external factor acquisition unit, including one or more processors, configured to acquire information of an external factor related to air conditioning control, including a floor average temperature calculated from an average value of temperatures measured in a plurality of the air conditioning control sections, an outside temperature that is a temperature outside the data center, and a server power consumption amount for each of the arrangement control sections that is a predicted amount when the virtual resource is arranged in the server;
a Situation determination unit, including one or more processors, configured to divide a value of each external factor into a predetermined range width, define a Situation classification by combining ranges divided for each external factor, and determine to which Situation classification the acquired information of the external factor belongs;
a control value search unit, including one or more processors, configured to calculate an air conditioning control value including at least a target temperature to be set for the plurality of air conditioners in each determined Situation classification;
an air conditioning control execution unit, including one or more processors, configured to execute control of the plurality of air conditioners using the calculated air conditioning control value;
a correspondence information generation unit, including one or more processors, configured to acquire an air conditioning control value of the plurality of air conditioners and an air conditioning power consumption amount of the plurality of air conditioners when control according to the air conditioning control value is performed, and generate control value power amount correspondence information in which the air conditioning power consumption amount is associated with the air conditioning control value of the plurality of air conditioners for each Situation classification;
an arrangement pattern calculation unit, including one or more processors, configured to calculate an arrangement pattern for arranging the virtual resource to be newly arranged in any of the plurality of servers;
a server power consumption amount estimation unit, including one or more processors, configured to estimate a server power consumption amount of a server group belonging to each arrangement control section for each calculated arrangement pattern; and
an arrangement pattern determination unit, including one or more processors, configured to acquire a Situation classification determination result using the server power consumption amount of each arrangement control section from the Situation determination unit, refer to the control value power amount correspondence information, and acquire, for each arrangement pattern, the air conditioning control values and the air conditioning power consumption amounts of the plurality of air conditioners in the Situation classification, and sum up a server power consumption amount for each arrangement control section, calculate a total amount of a total server power consumption amount that is the sum and the air conditioning power consumption amount in each arrangement pattern, and determine an arrangement pattern having a smallest calculated total amount as an arrangement pattern for arranging the virtual resource.

8. A program for causing a computer to function as the power amount reduction control device according to claim 1.
